(19) United States
(12) Patent Application Publication
(10) Pub. No.: US 2012/0015453 A1
(43) Pub. Date: Jan. 19, 2012

(54) PHOTOVOLTAIC CELL MANUFACTURING METHOD AND PHOTOVOLTAIC CELL MANUFACTURING APPARATUS

(75) Inventors: Kazuhiro Yamamuro, Chigasaki-shi (JP); Junpei Yuyama, Chigasaki-shi (JP); Katsumi Yamane, Chigasaki-shi (JP)

(73) Assignee: ULVAC, INC., Chigasaki-shi (JP)

(21) Appl. No.: 13/123,636

(22) PCT Filed: Nov. 2, 2009
(86) PCT No.: PCT/JP2009/005817

§ 371 Date: Apr. 11, 2011

(30) Foreign Application Priority Data
Nov. 4, 2008 (JP) 2008-283166

(51) Int. Cl. H01L 31/18; B23K 26/02

(52) U.S. Cl. 438/4; 29/705; 29/720; 219/121.83; 257/E31.11

(57) ABSTRACT

A photovoltaic cell manufacturing method includes: forming a photoelectric converter which has a plurality of compartment elements that are separated by a scribing line and in which adjacent compartment elements are electrically connected; detecting a structural defect existing in the compartment element; specifying a position in which the structural defect exists, as distance data indicating a distance between the structural defect and the scribing line that is closest to the structural defect; and removing a region in which the structural defect exists based on the distance data.

### BACKGROUND OF THE INVENTION

1. Field of the Invention

The present invention relates to a photovoltaic cell manufacturing method and a photovoltaic cell manufacturing apparatus, particularly, a photovoltaic cell manufacturing method and a photovoltaic cell manufacturing apparatus in which it is possible to quickly detect and repair a structural defect at a low cost.

This application claims priority from Japanese Patent Application No. 2008-283166 filed on Nov. 4, 2008, the contents of which are incorporated herein by reference in their entirety.

2. Background Art

In recent years, in view of efficient use of energy, photovoltaic cells have been more widely used than ever before.

Specifically, a photovoltaic cell in which a silicon single crystal is utilized has a high level of energy conversion efficiency per unit area.

However, in contrast, in the photovoltaic cell in which the silicon single crystal is utilized, a silicon single crystal ingot is sliced, and a sliced silicon wafer is used in the photovoltaic cell; therefore, a large amount of energy is spent for manufacturing the ingot, and the manufacturing cost is high.

Specifically, at the moment, in a case of realizing a photovoltaic cell having a large area which is placed out of doors or the like, when the photovoltaic cell is manufactured by use of a silicon single crystal, the cost considerably increases.

Consequently, as a low-cost photovoltaic cell, a photovoltaic cell that can be further inexpensively manufactured and that employs a thin film made of amorphous silicon is in widespread use.

An amorphous silicon photovoltaic cell uses semiconductor films of a layered structure that is referred to as a pin-junction in which an amorphous silicon film (i-type) is sandwiched between p-type and n-type silicon films, the amorphous silicon film (i-type) generating electrons and holes when receiving light.

An electrode is formed on both faces of the semiconductor films. The electrons and holes generated by sunlight actively transfer due to a difference in the electrical potentials between p-type and n-type semiconductors, and a difference in the electrical potentials between both faces of the electrodes is generated when the transfer thereof is continuously repeated.

As a specific structure of the amorphous silicon photovoltaic cell as described above, for example, a structure is employed in which a transparent electrode is formed as a lower electrode by forming TCO (Transparent Conductive Oxide) or the like on a glass substrate, and a semiconductor film composed of amorphous silicon and an upper electrode that becomes an Ag thin film or the like are formed thereon.

In the amorphous silicon photovoltaic cell that is provided with a photoelectric converter constituted of the foregoing upper and lower electrodes and the semiconductor film, the difference in the electrical potentials is small if each of the layers having a large area is only uniformly formed on the substrate, and there is a problem in that the resistance increases.

Consequently, the amorphous silicon photovoltaic cell is formed by, for example, forming compartment elements so as to electrically separate the photoelectric converter by a predetermined size, and by electrically connecting adjacent compartment elements with each other.

Specifically, a structure is adopted in which a groove that is referred to as a scribing line is formed on the photoelectric converter having a large area uniformly formed on the substrate by use of laser light or the like, a plurality of compartment elements formed in a longitudinal rectangular shape is obtained, and the compartment elements are electrically connected in series.

However, in the amorphous silicon photovoltaic cell having the foregoing structure, it is known that several structural defects occur during a manufacturing step therefor.

For example, in forming the amorphous silicon film, the upper electrode and the lower electrode may be locally short-circuited because particles mix thereto or pin holes occur therein.

In the photoelectric converter as mentioned above, when structural defects occur such that the upper electrode and the lower electrode are locally short-circuited with the semiconductor film interposed therebetween, the defects cause malfunctions such that power generation voltage or photoelectric conversion efficiency are degraded.

Consequently, in the process for manufacturing a conventional amorphous silicon photovoltaic cell, by detecting the structural defects such as the foregoing short-circuiting or the like and by removing the portions at which the structural defects occur, malfunction is improved.

A method for specifying the compartment element at which a structural defect exists by applying a bias voltage to the entire of each of compartment elements which are separated by scribing lines and by detecting Joule heat which is generated at short-circuited portions using an infrared light sensor is disclosed in, for example, Japanese Unexamined Patent Application, First Publication No. H9-266322.

Additionally, a photovoltaic cell manufacturing method for suppressing the occurrence of a defect which causes short-circuiting or the like at a scribing line formation portion is disclosed in Japanese Unexamined Patent Application, First Publication No. 2008-66453.

In cases where the portions at which the structural defect occurs on a compartment element are removed, a method is commonly known, for forming a groove (repair line) so as to surround the structural defect with laser light, electrically separating the region in which the structural defect exists from the portion at which the structural defect does not exist, and thereby preventing drawbacks such as short-circuiting.

When electrically separating the structural defect by the foregoing repair line, conventionally, aligning of the position which is irradiated with laser light is performed with reference to the end portion of the substrate at which the compartment element is to be formed.

However, in the case of setting the end portion of the substrate as alignment reference of laser light position and of forming the repair line that electrically separates into the region in which the structural defect exists and into the portion at which the structural defect does not exist, when a repair line is formed on a large-sized photovoltaic cell, a large-sized photovoltaic cell transfer stage capable of transferring the photovoltaic cell with a high level of precision is necessary.

A transfer stage, for example, on which a large-scale photovoltaic cell having a size exceeding one meter is mounted, and in which the movement precision of approximately several tens μm is maintained, is extremely expensive, and there is thereby a concern that the cost of manufacturing large-scale photovoltaic cells in high-volume production significantly increases.

The present was made in view of the above-described situation, and has an object to provide a photovoltaic cell manufacturing method and a photovoltaic cell manufacturing apparatus where a region in which the structural defect exists is accurately separated from a portion at which the structural defect does not exist, and it is possible to reliably remove the structural defect, even in a case where a low cost transfer stage having a low level of movement precision is used.

### SUMMARY OF THE INVENTION

In order to solve the above-described problem, the present invention provides the following photovoltaic cell manufacturing method.

That is, a photovoltaic cell manufacturing method of a first aspect of the present invention includes: forming a photoelectric converter which has a plurality of compartment elements that are separated by a scribing line and in which adjacent compartment elements are electrically connected; detecting a structural defect existing in the compartment element (defect detection step); specifying a position in which the structural defect exists, as distance data indicating a distance between the structural defect and the scribing line that is closest to the structural defect (defect position specifying step); and removing a region in which the structural defect exists based on the distance data (repairing step).

In the photovoltaic cell manufacturing method of the first aspect of the present invention, it is preferable that, when the position in which the structural defect exists is specified (defect position specifying step), a region including the structural defect and the scribing line which is closest to the structural defect be captured, an image be obtained by capturing the region, and the position in which the structural defect exists be specified as the distance data based on the image.

In the photovoltaic cell manufacturing method of the first aspect of the present invention, it is preferable that, when the region in which the structural defect exists is removed (repairing step), the region in which the structural defect exists be removed by laser light irradiation based on the distance data.

Additionally, in order to solve the above-described problem, the present invention provides the following photovoltaic cell manufacturing apparatus.

That is, in a photovoltaic cell manufacturing apparatus of a second aspect of the present invention, a photovoltaic cell includes a photoelectric converter which has a plurality of compartment elements that are separated by a scribing line and in which adjacent compartment elements are electrically connected. The apparatus includes: a defect detection section detecting a structural defect which exists in the compartment element; a defect position specifying section specifying a position in which the structural defect exists, as distance data indicating a distance between the structural defect and the scribing line that is closest to the structural defect; and a repairing section removing the region in which the structural defect exists based on the distance data.

In the photovoltaic cell manufacturing apparatus of the second aspect of the present invention, it is preferable that the defect position specifying section include an image-capturing device that captures a region including the structural defect and the scribing line which is closest to the structural defect.

In the photovoltaic cell manufacturing apparatus of the second aspect of the present invention, it is preferable that the repairing section be a laser device.

In the photovoltaic cell manufacturing apparatus of the second aspect of the present invention, it is preferable that the defect position specifying section and the repairing section include a common optical system therebetween.

In the photovoltaic cell manufacturing apparatus of the second aspect of the present invention, it is preferable that the defect position specifying section include: a camera obtaining an image by capturing the structural defect and the scribing line; and an optical system modulating a capturing magnification ratio so as to cause the structural defect and the scribing line to be included in the image.

In the photovoltaic cell manufacturing apparatus of the second aspect of the present invention, it is preferable that the defect position specifying section and the repairing section include a common optical system; the defect position specifying section uses a scribing line image which corresponds to the scribing line and which is included in the image and a structural defect image which corresponds to the structural defect and which is included in the image, and prepare position data and size data of the structural defect image based on the width of the scribing line image; the repairing section includes a laser device which irradiates the structural defect with laser light and a laser-irradiation-position transfer section which controls a relative position between the structural defect and the laser device; the repairing section controls a position of the laser-irradiation-position transfer section based on the position data and the size data of the structural defect image and the laser irradiation target point; and the laser device irradiate the compartment element with the laser light and remove the region in which the structural defect exists in a state where a position on the compartment element which is irradiated with the laser light coincides with a laser irradiation target point on the image. The laser-irradiation-position transfer section is, for example, an X-Y stage.

### EFFECTS OF THE INVENTION

According to the photovoltaic cell manufacturing method of the present invention, the position of the scribing line is specified based on the image data obtained by the image-capturing device in an image analyzing device, and it is possible to accurately determine the position on the compartment element which is irradiated with laser light with reference to laser light irradiation position data that are stored in advance.

In a conventional case, since movement of the stage on which a photovoltaic cell is mounted is controlled with reference to an alignment mark provided at the periphery of the substrate or an edge portion (end portion) of the substrate, an extremely expensive stage has been necessary which is capable of transferring the photovoltaic cell by a micro distance such as several μm after the large-scale photovoltaic cell having a length of several meters is moved by, for example, one meter.

In contrast, according to the present invention, after the substrate is preliminarily transferred such that a rough position at which a structural defect exists corresponds to the position of the image-capturing device, the image-capturing device captures the region in which the structural defect exists; the distance between the structural defect and the scribing line which is closest to the structural defect is calculated based on the image data obtained by the image-capturing device in the image analyzing device, and the position of the stage is controlled. Because of this, it is not necessary to use an expensive stage which can, for example, control with a high level of precision in a wide range of, for example, several μm to several meters.

For this reason, it is possible to accurately and electrically separate (remove) a structural defect by use of a low cost stage. Additionally, according to the photovoltaic cell manufacturing apparatus of the present invention, after the substrate is preliminarily transferred such that a rough position at which a structural defect exists corresponds to the position of the image-capturing device, the image-capturing device captures the region in which the structural defect exists; the distance between the structural defect and the scribing line which is closest to the structural defect is calculated based on the image data obtained by the image-capturing device in the image analyzing device, and the position of the stage is controlled.

Because of this, it is not necessary to use an expensive stage which can, for example, control with a high level of precision.

For this reason, it is possible to accurately and electrically separate (remove) a structural defect by use of a low cost stage.

### BRIEF DESCRIPTION OF THE DRAWINGS

FIG. 1 is an enlarged perspective view showing an example of an amorphous silicon type photovoltaic cell.

FIG. 2A is a cross-sectional view showing an example of the amorphous silicon type photovoltaic cell.

FIG. 2B is a cross-sectional view showing an example of the amorphous silicon type photovoltaic cell and is an enlarged view showing an enlarged part represented by reference numeral B of FIG. 2A.

FIG. 3 is a flowchart illustrating a photovoltaic cell manufacturing method of the present invention.

FIG. 4 is a cross-sectional view showing an example of a structural defect which exists in the photovoltaic cell.

FIG. 5 is a schematic diagram showing a defect position specifying-repairing apparatus.

FIG. 6 is a plan view illustrating a step for specifying a position of the structural defect.

FIG. 7A is a diagram schematically illustrating an optical system, a pathway of laser light, and a portion which is irradiated with laser light of the defect position specifying-repairing apparatus.

FIG. 7B is a diagram schematically illustrating an optical system, a pathway of laser light, and a portion which is irradiated with laser light of the defect position specifying-repairing apparatus.

### DESCRIPTION OF THE PREFERRED EMBODIMENTS

Hereinafter, the best mode of a photovoltaic cell manufacturing method and a photovoltaic cell manufacturing apparatus used therefor related to the present invention will be described with reference to drawings.

The embodiment is specifically explained for appropriate understanding of the scope of the present invention.

The technical scope of the invention is not limited to the embodiments described below, but various modifications may be made without departing from the scope of the invention.

In the respective drawings used in the explanation described below, in order to make the respective components be of understandable size in the drawing, the dimensions and the proportions of the respective components are modified as needed compared with the real components.

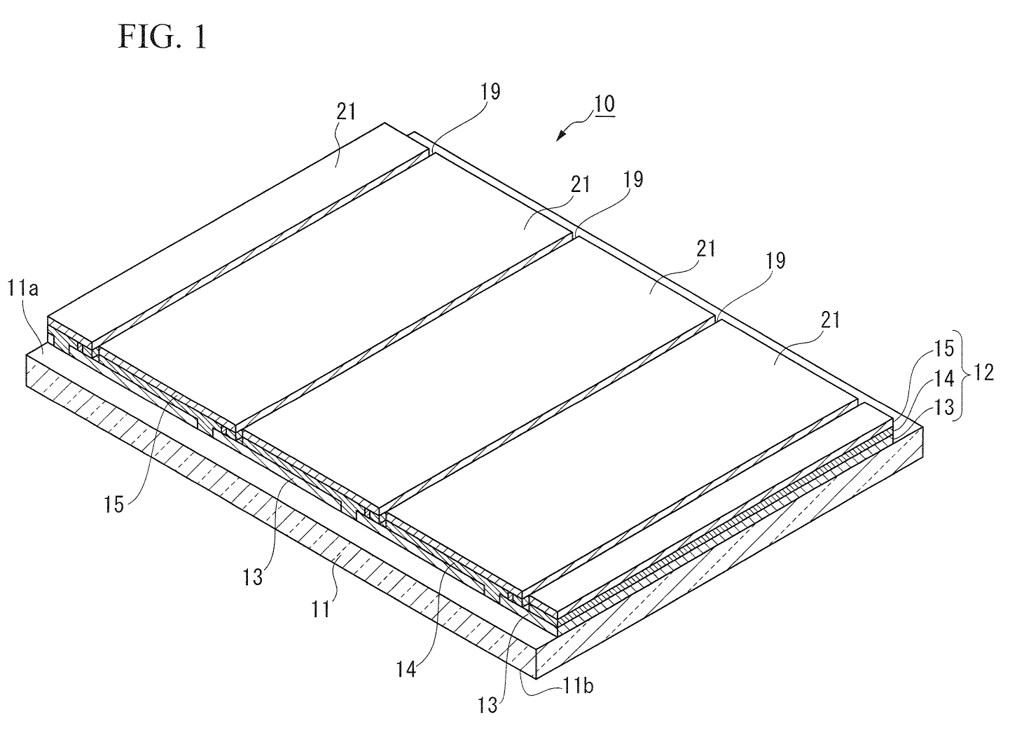

FIG. 1 is an enlarged perspective view showing an example of a main section of an amorphous silicon type photovoltaic cell which is manufactured by a photovoltaic cell manufacturing method of the present invention.

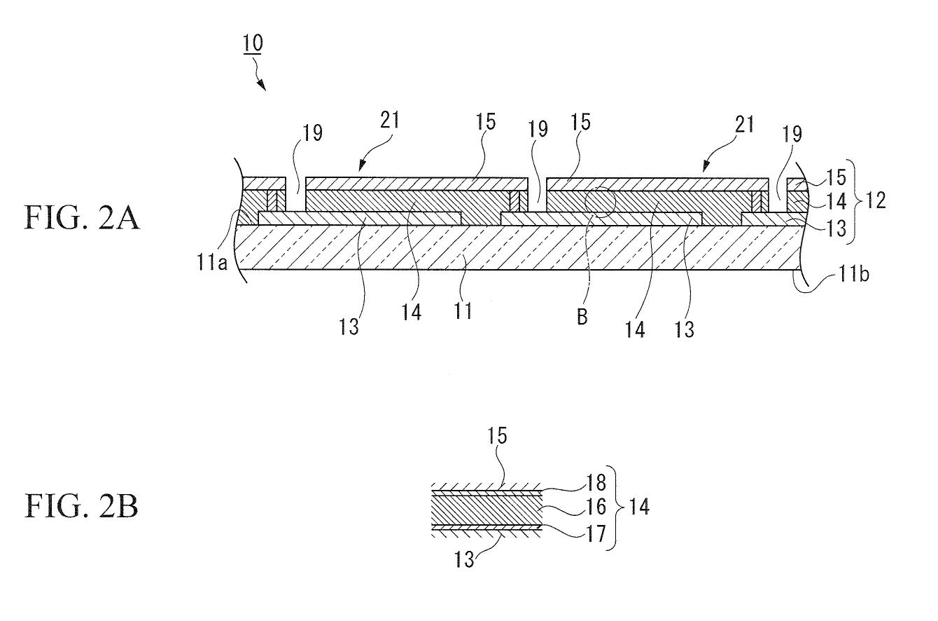

In addition, FIG. 2A is a cross-sectional view showing a layered structure of the photovoltaic cell shown in FIG. 1.

FIG. 2B is an enlarged view showing an enlarged part represented by reference numeral B of FIG. 2A. A photovoltaic cell 10 has a photoelectric converter 12 formed on a first face 11 a (one of faces) of a transparent substrate 11 having an insulation property.

The substrate 11 is formed of an insulation material having a high level of sunlight transparency and durability such as a glass or a transparent resin.

Sunlight is incident on a second face 11b (the other of faces) of the substrate 11.

In the photoelectric converter 12, a first electrode layer 13 (lower electrode), a semiconductor layer 14, and a second electrode layer 15 (upper electrode) are stacked in layers in order from the substrate 11.

The first electrode layer 13 (lower electrode) is formed of a transparent conductive material, for example, an oxide of metal (TCO) having an optical transparency such as ITO (Indium Tin Oxide).

In addition, the second electrode layer 15 (upper electrode) is formed of a conductive metal film such as Ag or Cu.

As shown in FIG. 2B, the semiconductor layer 14 has, for example, a pin-junction structure in which an i-type amorphous silicon film 16 is formed and sandwiched between a p-type amorphous silicon film 17 and an n-type amorphous silicon film 18.

Consequently, when sunlight is incident to the semiconductor layer 14, electrons and holes are generated, electrons and holes actively transfer due to a difference in the electrical potentials between the p-type amorphous silicon film 17 and the n-type amorphous silicon film 18; and a difference in the electrical potentials between the first electrode layer 13 and the second electrode layer 15 is generated when the transfer thereof is continuously repeated (photoelectric conversion).

The photoelectric converter 12 is divided by scribing lines 19 (scribe line) into a plurality of compartment elements 21, 21 . . . whose external form is a longitudinal rectangular shape. The compartment elements 21, 21 . . . are electrically separated from each other, and adjacent compartment elements 21 are electrically connected in series therebetween.

In this structure, the photoelectric converter 12 has a structure in which all of the compartment elements 21, 21 . . . are electrically connected in series.

In the structure, it is possible to extract an electrical current with a high degree of difference in the electrical potentials.

The scribing lines 19 are formed, for example, by forming grooves with a predetermined distance therebetween on the photoelectric converter 12 using laser light or the like after the photoelectric converter 12 was uniformly formed on the first face 11a of the substrate 11.

In addition, it is preferable that a protective layer (not shown) made of a resin of insulation or the like be further formed on the second electrode layer 15 (upper electrode) constituting the foregoing photoelectric converter 12.

A manufacturing method for manufacturing a photovoltaic cell having the foregoing structure will be described.

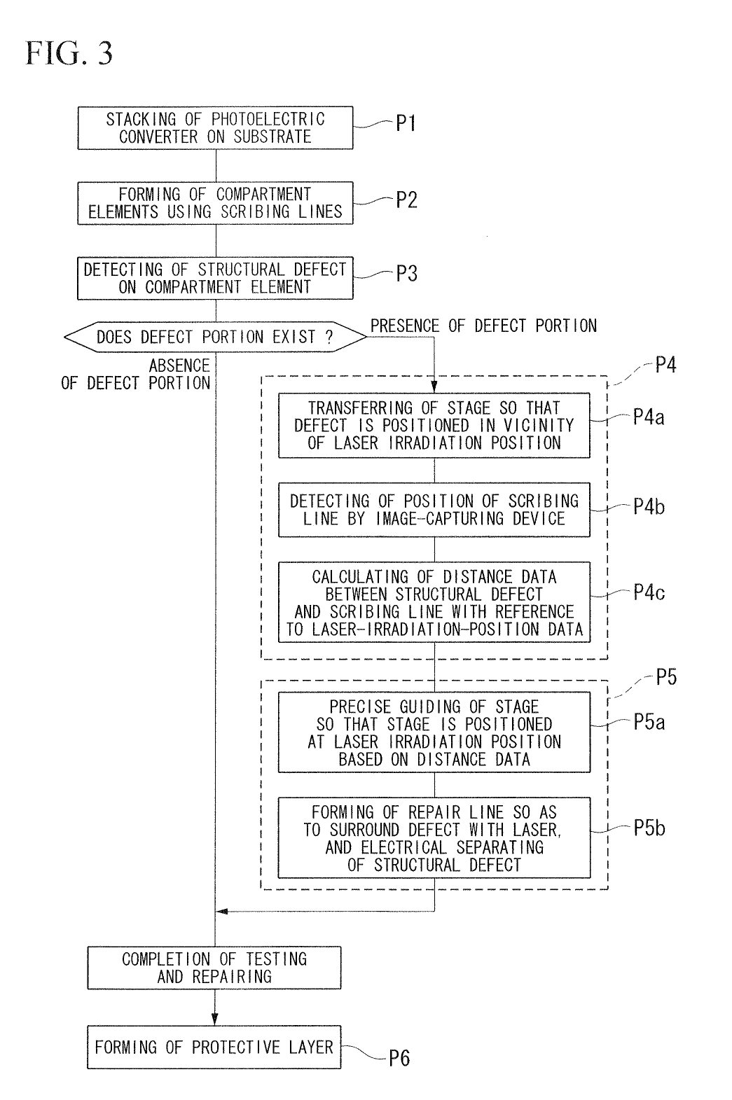

FIG. 3 is a flowchart illustrating a method for manufacturing the photovoltaic cell of the present invention in a stepwise manner.

In the method, specifically, steps between a step of specifying a structural defect and a step of repairing the structural defect will be described in detail.

Firstly, as shown in FIG. 1, a photoelectric converter 12 is formed on a first face 11a of a transparent substrate 11 (photoelectric converter formation step: P1).

As a structure of the photoelectric converter 12, for example, a structure in which a first electrode layer 13 (lower electrode), a semiconductor layer 14, and a second electrode layer 15 (upper electrode) are stacked in layers in order from the first face 11a of the substrate 11 is employed.

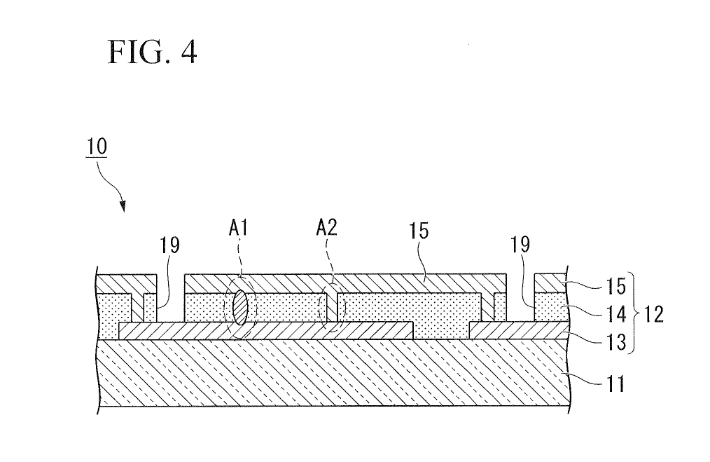

In the step of forming the photoelectric converter 12 having the foregoing structure, as shown in FIG. 4A, there is a case where malfunction is generated such as a structural defect A1 which is generated and caused by mixing impurities or the like into the semiconductor layer 14 (contamination) or a structural defect A2 at which microscopic pin holes are generated in the semiconductor layer 14. The foregoing structural defects A1 and A2 cause the first electrode layer 13 and the second electrode layer 15 to be locally short-circuited (leakage) therebetween, and degrade the power generation efficiency.

Next, scribing lines 19 (scribe line) are formed by irradiating the photoelectric converter 12 with, for example, a laser beam or the like; a plurality of separated compartment elements 21, 21 . . . which are formed in a longitudinal rectangular shape (compartment element formation step: P2).

In the photovoltaic cell 10 formed by the steps as described above, structural defects which exist in the compartment elements 21, 21 . . . (defects typified by the above-described A1 and A2) are detected (defect detection step: P3).

In a method for detecting the structural defects which exist in the compartment elements 21, 21 . . . in the defect detection step, a predetermined defect-detection apparatus is employed.

The types of the defect-detection apparatus are not limited.

As an example of the defect-detection method, a method is adopted in which resistances between adjacent compartment elements 21 and 21 are measured in the long side direction of the compartment element 21 by a predetermined distance, and a region where the resistances decrease, that is, a rough region where it is predicted that a defect causing short-circuiting exists is specified.

Additionally, for example, a method is adopted in which a bias voltage is applied to the entirety of a compartment element, and a rough region in which a structural defect exists is specified by detecting Joule heat generated in a short-circuited portion (portion in which a structural defect exists) with an infrared light sensor.

When the rough region in which a structural defect exists is confirmed (found) in the compartment elements 21, 21 . . . using the above-described method, subsequently, as a previous step for electrically separating the structural defect using laser light, exact positions of the structural defect are measured (defect position specifying step: P4).

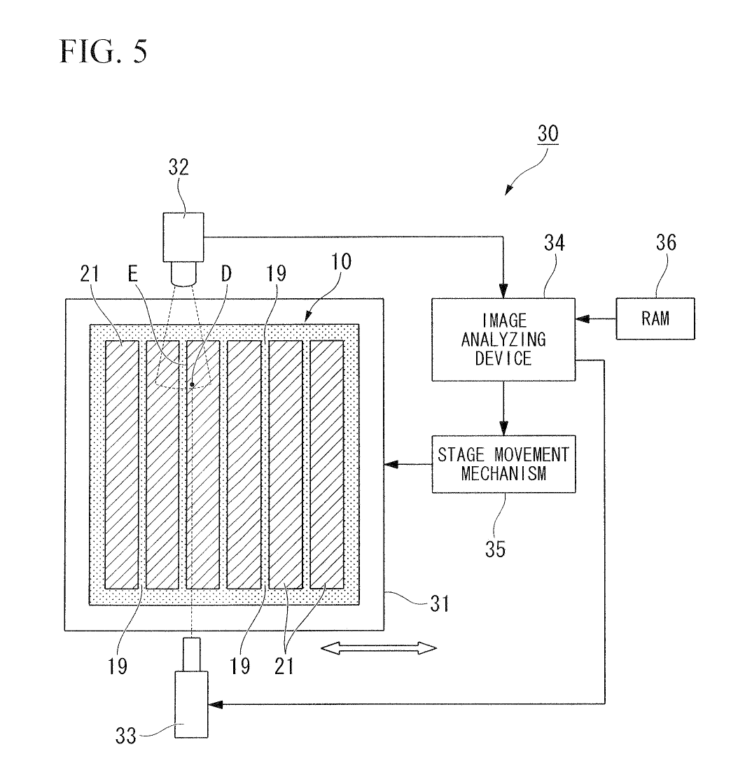

FIG. 5 is a schematic diagram showing a defect position specifying-repairing apparatus (photovoltaic cell manufacturing apparatus) of the present invention, which is used in a defect position specifying step or in a repairing step that is the next step.

The defect position specifying-repairing apparatus 30 includes a stage (transfer stage) 31 on which the photovoltaic cell 10 is mounted, and an image-capturing device 32 (camera) which captures the compartment elements 21, 21 . . . of the photovoltaic cell 10 mounted on the stage 31 with a high level of accuracy.

An image analyzing device 34 (defect position specifying section) is connected to the image-capturing device 32 (defect position specifying section).

In addition, a stage movement mechanism 35 (laser-irradiation-position transfer section, repairing section) controlling the movement of stage 31 is connected to the stage 31.

The stage movement mechanism 35 controls the relative position between the structural defect D and a laser device 33, and transfers the stage 31 with respect to the position of the laser device 33.

The image-capturing device 32 or the image analyzing device 34 constitutes the defect position specifying section.

Additionally, the defect position specifying-repairing apparatus 30 includes the laser device 33 (repairing section) which electrically separates off (removes) the structural defect

D from the portion at which the structural defect does not exist.

The laser device 33 irradiates the structural defect D or the region located near the structural defect D with laser light.

The stage 31 is a device on which the photovoltaic cell 10 is mounted, and transfers the photovoltaic cell 10 in X-axis and Y-axis directions by a predetermined degree of precision.

The image-capturing device 32 includes a camera provided with, for example, a solid-state image sensing device (CCD).

The laser device 33 is secured to a predetermined position. The substrate of the photovoltaic cell 10 is irradiated with laser light generated in the laser device 33.

As the laser device 33, for example, a device irradiating green laser light is employed.

The image analyzing device 34 detects the boundary between the compartment element 21 and the scribing line 19, that is, an edge line E along the long side direction of the compartment element 21, based on capturing data obtained by the image-capturing device 32.

Additionally, the image analyzing device 34 calculates the distance between the edge line E and the position of the structural defect D in the capturing data, in view of the definition or magnification ratio of the image (capturing magnification ratio). Also, a RAM 36 is connected to the image analyzing device 34; the irradiation position of the laser light emitted from the laser device 33 with relation to the stage 31 is stored in the RAM 36.

In the defect position specifying step (P4), firstly, the stage 31 is transferred so that the capturing scope of the image-capturing device 32 coincides with the rough region where the structural defect that was detected in the defect detection step (P3) of the previous step exists (P4a).

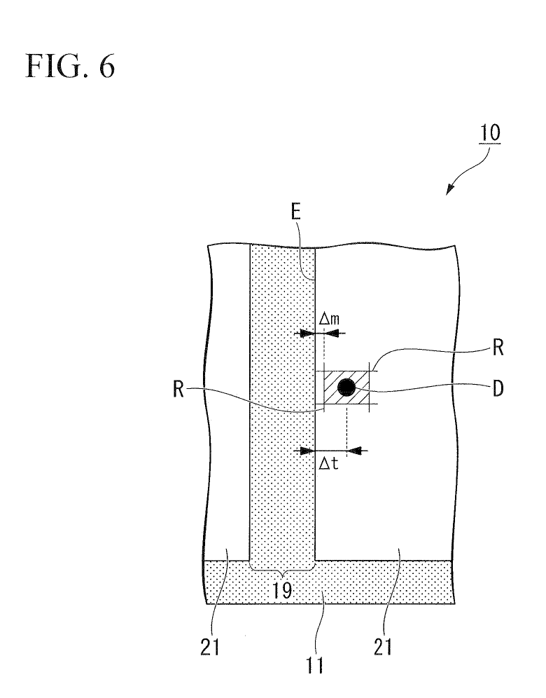

The image-capturing device 32 captures the region including the structural defect D which exists at the compartment element 21 and the scribing line 19 that is closest to the structural defect D at a predetermined magnification ratio and a definition, and obtains image data (refer to FIG. 6).

The image (region image, image data) that is obtained in the above-described manner includes: a scribing line image (image data of scribing line) corresponding to the scribing line 19 formed on the substrate 11; and a structural defect image (image data of structural defect) corresponding to the structural defect D generated in the photoelectric converter 12.

The image data including the foregoing scribing line image and structural defect image is input to the image analyzing device 34.

In the image analyzing device 34, firstly, the position of the scribing line 19 is specified based on the input image data (P4b). In the specifying of the scribing line 19, it is only necessary to specify the position of the edge E of the scribing line 19 based on a difference in contrasting in the image which is caused by, for example, the difference in a material or the difference in height (difference in thickness) between the formation portion of the compartment element 21 and the region of the scribing line 19. Next, laser light irradiation position data relative to the stage 31, which is stored in the RAM 36 in advance, is read out with reference to the RAM 36.

The distance At between the structural defect D and the edge E of the scribing line 19 is calculated (P4c) based on the irradiation position data and the position of the edge E of the scribing line 19 data.

Subsequently, in the repairing step (P5), the stage 31 is precisely guided (P5a) so that the position which is irradiated with laser light coincides with the position which is located adjacent to the structural defect D, based on the distance data At between the structural defect D and the scribing line 19, which is obtained in the defect position specifying step (P4).

Consequently, the compartment element 21 is focused and irradiated with laser light from the laser device 33, and a repair line R surrounding the structural defect D is formed (P5b).

By forming the repair line R, the structural defect D is electrically separated (removed) from the other region where defects do not occur.

When the repair line R is formed in the above-described manner, since the position of the edge E of the scribing line 19 and the position which is irradiated with laser light are accurately detected, it is possible to minimize the distance Am between the repair line R and the edge E of the scribing line 19.

Therefore, it is possible to form the repair line R so that the position of the repair line R is extremely close to the position of the edge E of the scribing line 19.

When the repair line R is formed, the layers (photoelectric converter) which is from the first electrode layer (lower electrode) 13 to the second electrode layer (upper electrode) 15 are removed (refer to FIG. 2).

According to the present invention, the position of the scribing line 19 is specified based on the image data obtained by the image-capturing device 32 in the image analyzing device 34, and it is possible to accurately determine the position on the compartment element 21 which is irradiated with laser light with reference to laser light irradiation position data that is stored in advance.

Because of this, it is possible to emit laser light while maintaining the minimized distance between the repair line R and the edge E of the scribing line 19, and it is possible to suppress and minimize the number of the generated structural defects which remain between the repair line R and the scribing line 19.

For this reason, it is possible to head off reaction that many structural defects remain in a finished product.

In a conventional case, since movement of the stage on which a photovoltaic cell is mounted is controlled with reference to an edge portion (end portion) of the substrate, an extremely expensive stage has been necessary which is capable of transferring the photovoltaic cell by a micro distance such as several μm after the large-scale photovoltaic cell having a length of several meters is moved by, for example, one meter.

In contrast, according to the present invention, after the substrate is preliminarily transferred such that a rough position at which a structural defect exists corresponds to the position of the image-capturing device 32, the image-capturing device 32 captures the region in which the structural defect exists; the distance between the structural defect D and the scribing line 19 which is closest to the structural defect D is calculated based on the image data obtained by the image-capturing device 32 in the image analyzing device 34, and the position of the stage 31 is controlled.

Because of this, it is not necessary to use an expensive stage which can, for example, control with a high level of precision in a wide range of, for example, several μm to several meters.

For this reason, it is possible to accurately and electrically separate (remove) the structural defect D by use of a low cost stage.

Next, a constitution of the defect position specifying-repairing apparatus 30 will be specifically described.

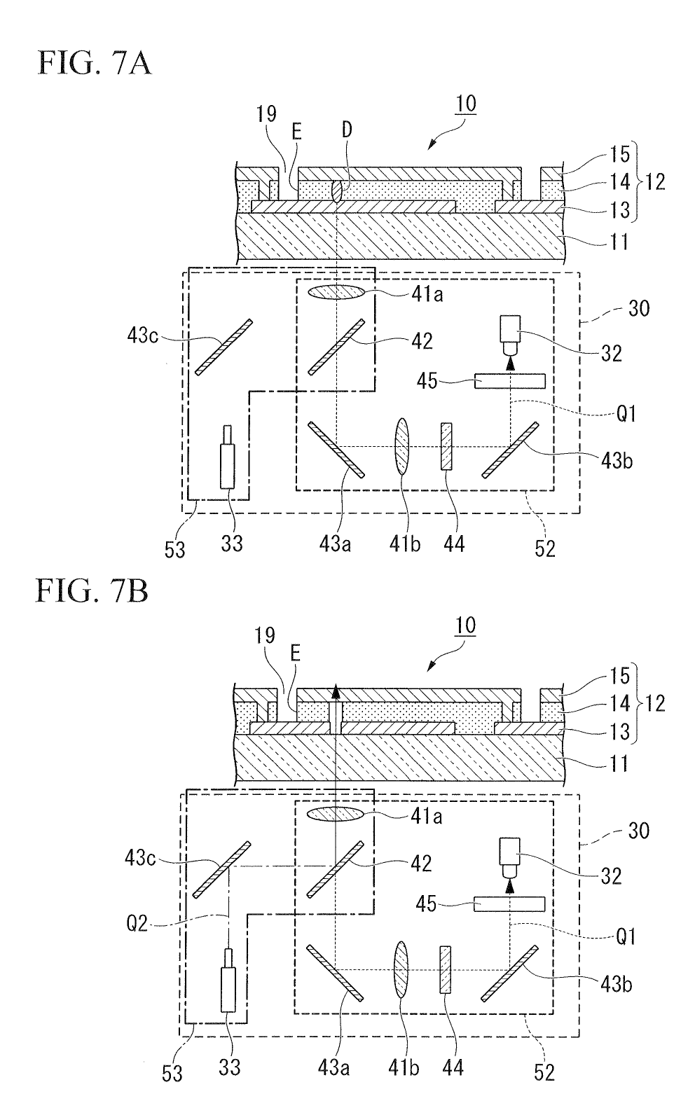

FIGS. 7A and 7B are diagrams schematically illustrating an optical system of the defect position specifying-repairing apparatus 30, a pathway of laser light, and the portion which is irradiated with laser light.

In the defect position specifying-repairing apparatus 30 shown in FIGS. 7A and 7B, a part of the optical system specifying the position of the structural defect D and a part of the optical system repairing the defect are common in each other.

That is, in the defect position specifying-repairing apparatus 30, the defect position specifying section 52 and the repairing section 53 have a common optical system therebetween.

The optical system of the defect position specifying-repairing apparatus 30 is constituted of, for example, lenses 41a and 41b, a half mirror 42, mirrors 43a, 43b, and 43c, a filter 44, a magnification-ratio modulation portion 45, a laser device 33, and an image-capturing device 32.

Additionally, the defect position specifying section 52 is constituted of the lenses 41a and 41b, the half mirror 42, the mirrors 43a and 43b, the filter 44, the magnification-ratio modulation portion 45, and the image-capturing device 32.

Also, the repairing section 53 is constituted of the lens 41a, the half mirror 42, the mirror 43c, and the laser device 33.

That is, the lens 41a and the half mirror 42 are common optical systems in the defect position specifying section 52 and the repairing section 53.

The magnification-ratio modulation portion 45 is an optical system element (optical system) that modulates the capturing magnification ratio so that the region including the structural defect D and the scribing line 19 is captured by the image-capturing device 32.

In other words, the magnification-ratio modulation portion 45 is an optical system element that modulates the capturing magnification ratio so that the above-described scribing line image and the structural defect image are included in the image (region image) obtained by the image-capturing device 32.

As the structure of the magnification-ratio modulation portion 45, a structure is employed in which, for example, a plurality of lenses is arranged on an optical path Q1 and which modulates the capturing magnification ratio by changing the distance between the lenses.

Additionally, the image-capturing device 32 may include a structure which modulates the capturing magnification ratio.

In order to specify the position of the structural defect D, when the region including the structural defect D and the scribing line 19 is captured and the image thereof is obtained, a picture including the structural defect D and the scribing line 19 that is closest to the structural defect D passes through the optical path Q1 from the lens 41a via the half mirror 42, the mirror 43a, the lens 41b, the filter 44, the mirror 43b, and the magnification-ratio modulation portion 45, and is thereby formed as an image in the image-capturing device 32.

That is, in the defect position specifying section 52, the picture including the structural defect D and the scribing line 19 that is closest to the structural defect D is captured, and the image thereof is obtained.

On the other hand, when the structural defect D is repaired, the laser light emitted from the laser device 33 passes through an optical path Q2 via the mirror 43c, the half mirror 42, and the lens 41a, and the structural defect D is irradiated with the laser light.

That is, the structural defect D is irradiated with laser light by the repairing section 53.

In the above-described manner, in the defect position specifying-repairing apparatus 30, it is preferable that a part of optical path (a part of optical system) be shared in use in the optical path Q1 and the optical path Q2, and a member constituting the optical system be disposed on one base plate.

In addition, in the repairing step, it is not necessary to provide a member such as shutter or the like on the optical path Q1 during laser light irradiation.

In a case where the laser light is, for example, a green laser, when a filter 44 cutting a wavelength-band of the green (green color) light is provided on the optical path Q1, it is possible to repair the structural defect D while checking the state where the structural defect D is repaired on the image.

After the steps described above, all of the structural defects D which exist in the compartment element 21 are electrically separated (removed), thereafter, a step for forming a protective layer (P6) or the like is performed, and a photovoltaic cell as product is obtained.

### Modified Example

Next, a modified example of the above-described embodiment will be specifically described.

In the above-described embodiment, the image-capturing device 32 modulates the magnification ratio, captures the region including the structural defect D and the scribing line 19, and obtains the image (region image) including the scribing line image and the structural defect image.

In this case, a reference distance is unclear in the image.

In the modified example, firstly, an image reference point in the image (for example, center point) is set.

In other cases, the image reference point may be determined in advance so as to be a constant position in the image at all times.

Additionally, the image reference point may be optionally determined in the image.

The point on the substrate corresponding to the image reference point when the image is obtained at the time of capturing is a substrate reference point.

Next, due to an image processing, the positions of the scribing line image and the structural defect image and the sizes thereof in the image are calculated.

Because of this, position data and size data of the structural defect image in the image and width data of the scribing line image in the image are prepared.

The position data of the structural defect image in the image is prepared with reference to the image reference point.

Subsequently, by use of the width of a practical scribing line which is stored and the width data of the scribing line image in the image, the reference distance of the image is set.

Next, by use of the position data and the size data of the structural defect image in the image and the reference distance, distance data of a practical structural defect from the substrate reference point and size data of a practical structural defect are prepared.

Subsequently, laser-irradiation-position data used for forming the repair line R surrounding the structural defect D is prepared based on the distance data of the practical structural defect and the size data of the practical structural defect.

Movement data of an X-Y stage 31 is prepared based on the laser-irradiation-position data.

As shown in FIGS. 7A and 7B, the defect position specifying section 52 and the repairing section 53 have a common optical system.

That is, since the optical paths Q1 and Q2 in the lens 41a and the half mirror 42 coincide with each other, the point of the substrate corresponding to the image reference point can coincide with the point of the substrate which is irradiated with laser light.

Next, the compartment element 21 is irradiated with laser based on the laser-irradiation-position data while the X-Y stage 31 is transferred based on the movement data of the X-Y stage 31.

As described above, by use of the image (region image) obtained by the image-capturing device 32, it is possible to calculate the position and the size of a practical structural defect D which occurs in the photoelectric converter 12.

Additionally, since it is possible to determine the range in which the stage 31 (laser-irradiation-position transfer section) is transferred relative to the position of the laser device 33 with reference to the image data, it is not necessary to determine the coordinates of the entirety of the substrate.

The laser device 33 irradiates the compartment element 21 with laser light while transferring the stage 31 so that the position on the compartment element 21 (position on which the repair line R is formed) which is irradiated with laser light coincides with the laser irradiation target point (image reference point) on the image (region image).

As a result, the repair line R is formed, the layers (photoelectric converter) from the first electrode layer (lower electrode) 13 to the second electrode layer (upper electrode) 15 are removed.

### INDUSTRIAL APPLICABILITY

As described above in detail, the present invention is useful to a photovoltaic cell manufacturing method and a photovoltaic cell manufacturing apparatus where a region in which the structural defect exists is accurately separated from a portion at which the structural defect does not exist, and it is possible to reliably remove the structural defect, even in a case where a low cost transfer stage having a low level of movement precision is used.

What is claimed is:

1. A photovoltaic cell manufacturing method comprising:
forming a photoelectric converter which has a plurality of compartment elements that are separated by a scribing line and in which adjacent compartment elements are electrically connected;
detecting a structural defect existing in the compartment element;
specifying a position in which the structural defect exists, as distance data indicating a distance between the structural defect and the scribing line that is closest to the structural defect; and
removing a region in which the structural defect exists based on the distance data.

2. The photovoltaic cell manufacturing method according to claim 1, wherein when the position in which the structural defect exists is specified, a region including the structural defect and the scribing line which is closest to the structural defect is captured, an image is obtained by capturing the region, and the position in which the structural defect exists is specified as the distance data based on the image.

3. The photovoltaic cell manufacturing method according to claim 1, wherein when the region in which the structural defect exists is removed, the region in which the structural defect exists is removed by laser light irradiation based on the distance data.

4. An apparatus for manufacturing a photovoltaic cell, the photovoltaic cell including a photoelectric converter which has a plurality of compartment elements that are separated by a scribing line and in which adjacent compartment elements are electrically connected, the apparatus comprising:
a defect detection section detecting a structural defect which exists in the compartment element;
a defect position specifying section specifying a position in which the structural defect exists, as distance data indicating a distance between the structural defect and the scribing line that is closest to the structural defect; and
a repairing section removing the region in which the structural defect exists based on the distance data.

5. The photovoltaic cell manufacturing apparatus according to claim 4, wherein the defect position specifying section comprises an image-capturing device that captures a region including the structural defect and the scribing line which is closest to the structural defect.

6. The photovoltaic cell manufacturing apparatus according to claim 4, wherein the repairing section is a laser device.

7. The photovoltaic cell manufacturing apparatus according to claim 4, wherein the defect position specifying section and the repairing section comprise a common optical system.

8. The photovoltaic cell manufacturing apparatus according to claim 4, wherein the defect position specifying section comprises:
a camera obtaining an image by capturing the structural defect and the scribing line; and
an optical system modulating a capturing magnification ratio so as to cause the structural defect and the scribing line to be included in the image.

9. The photovoltaic cell manufacturing apparatus according to claim 8, wherein the defect position specifying section and the repairing section comprise a common optical system;
the defect position specifying section uses a scribing line image which corresponds to the scribing line and which is included in the image and a structural defect image which corresponds to the structural defect and which is included in the image, and prepares position data and size data of the structural defect image based on a width of the scribing line image;
the repairing section comprises a laser device which irradiates the structural defect with laser light and a laser-irradiation-position transfer section which controls a relative position between the structural defect and the laser device;
the repairing section controls a position of the laser-irradiation-position transfer section based on the position data and the size data of the structural defect image and a laser irradiation target point; and
the laser device irradiates the compartment element with the laser light and removes the region in which the structural defect exists in a state where a position on the compartment element which is irradiated with the laser light coincides with a laser irradiation target point on the image.
